(19) United States
(12) Patent Application Publication
(10) Pub. No.: US 2022/0102657 A1
(43) Pub. Date: Mar. 31, 2022

(54) PHOTOELECTRIC CONVERSION ELEMENT AND SOLAR BATTERY MODULE

(71) Applicant: SHARP KABUSHIKI KAISHA, Sakai City (JP)

(72) Inventors: SHINTARO MIYANISHI, Sakai City (JP); Shinya UEGAKI, Sakai City (JP); HIROSHI SUGIMURA, Sakai City (JP)

(21) Appl. No.: 17/481,832

(22) Filed: Sep. 22, 2021

(30) Foreign Application Priority Data
Sep. 25, 2020 (JP) 2020-160827
Aug. 27, 2021 (JP) 2021-139060

(51) Int. Cl. H01L 51/42; H01L 51/44; H01L 27/30

(52) U.S. Cl. CPC H01L 51/422; H01L 51/447; H01L 2251/303; H01L 27/301; H01L 51/448

(57) ABSTRACT

The photoelectric conversion element includes a surface electrode, a backside electrode, a light absorption layer disposed between the surface electrode and the backside electrode, and a hole transport layer disposed between the backside electrode and the light absorption layer. The light absorption layer contains a conical or elliptical conical crystal. The crystal has a perovskite layer containing a perovskite compound. The hole transport layer contains an inorganic material. A solar battery module includes a plurality of photoelectric conversion elements connected in series. The photoelectric conversion elements are the aforementioned photoelectric conversion element.

### BACKGROUND OF THE INVENTION

### Field of the Invention

The present invention relates to a photoelectric conversion element and a solar battery module.

### Description of the Background Art

Photoelectric conversion elements are used for e.g. optical sensors, copiers, solar battery modules, and the like. Above all, the solar battery modules have been spread in earnest as a representative method using a renewable energy. As the solar battery module, solar battery modules using an inorganic photoelectric conversion element (e.g. silicon solar battery module, CIGS solar battery module, and CdTe solar battery module, etc.) have been spread.

On the other hand, as the solar battery module, solar battery modules using an organic photoelectric conversion element (e.g. organic thin-film solar battery module, dye-sensitized solar battery module) are also being considered. Such a solar battery module using an organic photoelectric conversion element can be produced by a coating treatment without using a vacuum process, and therefore has the potential to significantly reduce the production cost. Thus, the solar battery modules using the organic photoelectric conversion element are expected as next-generation solar battery modules.

In recent years, as the organic photoelectric conversion element, a photoelectric conversion element using a compound having a perovskite type crystal structure (hereinafter, referred to as perovskite compound in some cases) for a light absorption layer has been considered. Examples of the perovskite compound includes a lead complex. The photoelectric conversion element using the perovskite compound for the light absorption layer is excellent in photoelectric conversion efficiency. In addition, it is considered that a photoelectric conversion efficiency is further improved by using a carbon nanotube as a hole transporting material in a photoelectric conversion element using a perovskite compound (JP 2014-72327A).

However, the photoelectric conversion element using the perovskite compound for the light absorption layer tends to have a low photoelectric conversion efficiency.

The present invention has been made in view of the aforementioned problems, and an object of the present invention is to provide a photoelectric conversion element and a solar battery module that are excellent in photoelectric conversion efficiency.

### SUMMARY OF THE INVENTION

The photoelectric conversion element according to an embodiment of the present invention has a surface electrode, a backside electrode, a light absorption layer disposed between the surface electrode and the backside electrode, and a hole transport layer disposed between the backside electrode and the light absorption layer. The light absorption layer contains a conical or elliptical conical crystal. The crystal has a perovskite layer containing a perovskite compound. The hole transport layer contains an inorganic material.

A solar battery module according to another embodiment of the present invention includes a plurality of photoelectric conversion elements connected in series. The photoelectric conversion elements refer to the aforementioned photoelectric conversion element.

The photoelectric conversion element and the solar battery module according to the present invention are excellent in the photoelectric conversion efficiency.

### BRIEF DESCRIPTION OF THE DRAWINGS

FIG. 1 is a diagram illustrating an example of a photoelectric conversion element according to an embodiment of the present invention.

FIG. 2 is a diagram illustrating a primitive unit lattice of a perovskite crystal structure.

FIG. 3 is a diagram illustrating an example of the crystal structure.

FIG. 4 is a diagram illustrating a band structure of an ordinary perovskite crystal.

FIG. 5 is a diagram illustrating a band structure of the crystal in FIG. 3.

FIG. 6 is a diagram illustrating an example of a crystal different from the crystal in FIG. 3.

FIG. 7 is a diagram illustrating an example of a crystal different from the crystals in FIG. 3 and FIG. 6.

FIG. 8 is a diagram illustrating an example of a crystal different from the crystals in FIG. 3, FIG. 6, and FIG. 7.

FIG. 9 is a diagram illustrating an example of a crystal different from the crystals in FIG. 3, and FIG. 6 to FIG. 8.

FIG. 10 is a diagram illustrating an optical path of light incident on the crystal in FIG. 9.

FIG. 11 is an enlarged view of a light absorption layer containing the crystal in FIG. 9.

FIG. 12 is a diagram illustrating a band structure of the light absorption layer in FIG. 11.

FIG. 13 is a diagram illustrating an example of a crystal different from the crystals in FIG. 3, and FIG. 6 to FIG. 9.

FIG. 14 is a diagram illustrating a band structure of the crystal in FIG. 13.

FIG. 15 is a diagram illustrating an example of a further preferable aspect of the crystal in FIG. 13.

FIG. 16 is a diagram illustrating an example of a crystal different from the crystals in FIG. 3, FIG. 6 to FIG. 9, and FIG. 13.

FIG. 17 is a diagram illustrating an example of a solar battery module according to an embodiment of the present invention.

FIG. 18 is an optical microscope image of a light absorption layer of a photoelectric conversion element produced in Comparative Example.

FIG. 19 is an optical microscope image of a light absorption layer of a photoelectric conversion element produced in Example.

FIG. 20 is an optical microscope image of the light absorption layer of the photoelectric conversion element produced in Example.

FIG. 21 is an optical microscope image of the light absorption layer of the photoelectric conversion element produced in Example.

### DESCRIPTION OF THE PREFERRED EMBODIMENTS

The embodiments of the present invention will be explained below with reference to the figures. Note that the present invention is not limited to the embodiments at all, and can be implemented with appropriate changes within the scope of the purpose of the present invention. In the figures, the same or equivalent parts are numbered with the same reference numerals, and explanation of the same or equivalent parts are omitted in some cases. The scale of each component in the figures is not accurate in some cases. Acryl and methacryl are comprehensively referred to as “(meth)acryl” in some cases. Acrylate and methacrylate are comprehensively referred to as “(meth)acrylate” in some cases. As each material to be explained in the embodiments of the present invention, only one material may be used, or two or more materials may be used in combination, unless otherwise specified. In the embodiments of the present invention, the terms “surface” and “backside” are used for convenient distinction and do not specify the directions of the surface and backside in actual use.

### The First Embodiment: Photoelectric Conversion Element

The first embodiment of the present invention relates to a photoelectric conversion element. The photoelectric conversion element according to the first embodiment has a surface electrode, a backside electrode, a light absorption layer disposed between the surface electrode and the backside electrode, and a hole transport layer disposed between the backside electrode and the light absorption layer. The light absorption layer contains a conical or elliptical conical crystal (hereinafter referred to as a crystal (α) in some cases). The crystal (α) has a perovskite layer containing a perovskite compound. The hole transport layer contains an inorganic material.

In the photoelectric conversion element according to the first embodiment, the light absorption layer includes the crystal (α). The crystals (α) is excellent in a photoelectric conversion efficiency, as described later. Thus, the photoelectric conversion element according to the first embodiment can exhibit an excellent photoelectric conversion efficiency.

The photoelectric conversion element according to the first embodiment may further include other layers in addition to the surface electrode, the backside electrode, the light absorption layer, and the hole transport layer. Examples of the other layers include a substrate and an electron transport layer.

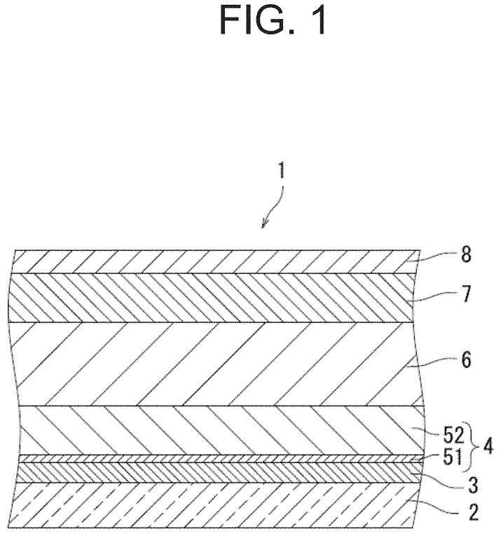

First, an example of the photoelectric conversion element according to the first embodiment will be explained in outline with reference to FIG. 1. A photoelectric conversion element 1 illustrated in FIG. 1 has a substrate 2, a surface electrode 3, an electron transport layer 4, a light absorption layer 6, a hole transport layer 7, and a backside electrode 8 in this order from one side. The electron transport layer 4 has a two-layer structure including a dense titanium oxide layer 51 on the surface electrode 3 side and a porous titanium oxide layer 52 on the light absorption layer 6 side. The light absorption layer 6 contains the crystal (α). In the photoelectric conversion element 1, for example, the substrate 2-side face is irradiated with light (e.g. solar light) when used. However, in the photoelectric conversion element 1, the backside electrode 8-side face may be irradiated with light when used. In the following, first, the crystal (α) will be explained in detail.

Crystal (α)

The crystal (α) has a conical or elliptical conical shape. The crystal (α) may have a hollow structure or a non-hollow structure. That means, the crystal (α) has a non-hollow conical shape, a non-hollow elliptical conical shape, a hollow conical shape, or a hollow elliptical conical shape. The crystal (α) has a perovskite layer containing a perovskite compound. A major axis length of the crystal (α) is preferably 5 μm or larger to 50 μm or smaller, more preferably 7 μm or larger to 20 μm or smaller. An aspect ratio (ratio of the major axis length to the minor axis length) of the crystal (α) is preferably 5 or higher to 30 or lower, more preferably 10 or higher to 20 or lower. When the major axis length and the aspect ratio of the crystal (α) are within the above ranges, the photoelectric conversion efficiency of the photoelectric conversion element 1 can be further improved. The major axis length and the aspect ratio of the crystal (α) can be measured by the same method as described in Example.

Specifically, there is a tendency that if the major axis length of the crystal (α) is smaller than 5 μm, the crystals (α) are aligned almost perpendicularly to the film face of the light absorption layer 6. Since such a light absorption layer 6 is a dense layer, there is a tendency that a light confining effect attributed to the crystal (α) described later is hardly obtained. In addition, there is a tendency that if the major axis length of the crystal (α) is larger than 50 μm, the crystals (α) are aligned almost parallel to the film face of the light absorption layer 6. Such a light absorption layer 6 tends to cause a region having no crystal (α) (a region where the electron transport layer 4 or the hole transport layer 7 are exposed). As a result, the photoelectric conversion element 1 has a tendency that a carrier extraction efficiency from the electrodes (surface electrode 3 and backside electrode 8) slightly decreases. As described above, when the major axis length of the crystal (α) is 5 μm or larger to 50 μm or smaller, the carrier extraction efficiency from the electrodes increases in the photoelectric conversion element 1.

The perovskite compound contained in the crystal (α) is preferably a compound represented by the following general formula (1) (hereinafter referred to as a perovskite compound (1) in some cases), from the viewpoint of further improving the photoelectric conversion efficiency of the photoelectric conversion element 1.

[Formula 1]

ABX₃ (1)

In general formula (1), A represents an organic molecule, B represents a metal atom, and X represents a halogen atom. In general formula (1), the three Xs may be the same as or different from each other.

The Perovskite compound (1) is an organic-inorganic hybrid compound. The organic-inorganic hybrid compound refers to a compound composed of inorganic and organic materials. The photoelectric conversion element 1 using the perovskite compound (1) that is an organic-inorganic hybrid compound is also referred to as an organic-inorganic hybrid photoelectric conversion element.

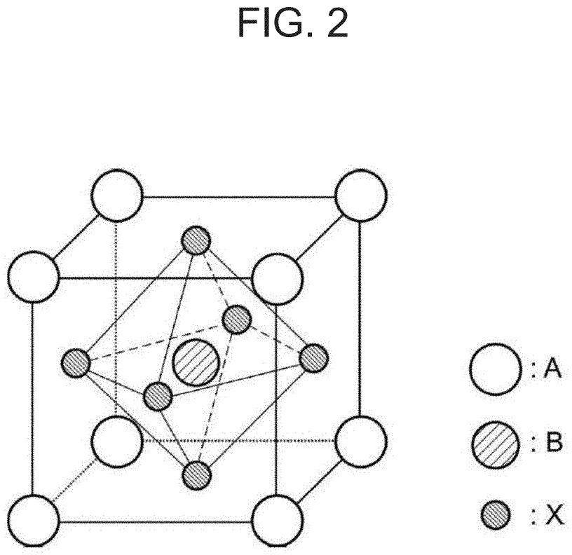

FIG. 2 is a schematic diagram of a cubic primitive unit lattice of the crystal structure constituting the perovskite compound (1). This primitive unit lattice includes organic molecules A positioned at respective vertexes, a metal atom B positioned at a body center, and halogen atoms X positioned at respective face centers.

It is possible to confirm whether the light absorbing material has the cubic primitive unit lattice, by using an X-ray diffraction method. Specifically, the light absorption layer 6 containing a light absorbing material is prepared on a glass plate, then the light absorption layer 6 is recovered in a powder form, and a diffraction pattern of the recovered powdered light absorption layer 6 (light absorbing material) is measured using a powder X-ray diffractometer. Alternatively, the light absorption layer 6 is recovered in a powder form from the photoelectric conversion element 1, and a diffraction pattern of the recovered powdered light absorption layer 6 (light absorbing material) is measured using a powder X-ray diffractometer.

Examples of the organic molecules represented by A in general formula (1) include an alkylamine, an alkylammonium, a nitrogen-containing heterocyclic compound, and the like. In the perovskite compound (1), the organic molecules represented by A may be only one kind of organic molecule or two or more kinds of organic molecules.

Examples of the alkylamine include methylamine, ethylamine, propylamine, butylamine, pentylamine, hexylamine, dimethylamine, diethylamine, dipropylamine, dibutylamine, dipentylamine, dihexylamine, trimethylamine, triethylamine, tripropylamine, tributylamine, tripentylamine, trihexylamine, ethylmethylamine, methylpropylamine, butylmethylamine, methylpentylamine, hexylmethylamine, ethylpropylamine, ethylbutylamine, and the like.

The alkylammonium is an ionized form of the aforementioned alkylamine. Examples of the alkylammonium include methylammonium (CH₃NH₃), ethylammonium, propylammonium, butylammonium, pentylammonium, hexylammonium, dimethylammonium, diethylammonium, dipropylammonium, dibutylammonium, dipentylammonium, dihexylammonium, trimethylammonium, triethylammonium, tripropylammonium, tributylammonium, tripentylammonium, trihexylammonium, ethylmethylammonium, methylpropylammonium, butylmethylammonium, methylpentylammonium, hexylmethylammonium, ethylpropylammonium, and ethylbutylammonium, and the like.

Examples of the nitrogen-containing heterocyclic compound include imidazole, azole, pyrrole, aziridine, azirine, azetidine, azete, azole, imidazoline, carbazole, and the like. The nitrogen-containing heterocyclic compound may be in an ionized form. As the nitrogen-containing heterocyclic compound in the ionized form, phenethylammonium is preferable.

As the organic molecules represented by A, methylamine, ethylamine, propylamine, butylamine, pentylamine, hexylamine, methylammonium, ethylammonium, propylammonium, butylammonium, pentylammonium, hexylammonium, or phenethylammonium is preferable, above all, methylamine, ethylamine, propylamine, methylammonium, ethylammonium, or propylammonium is more preferable, and above all, methylammonium is even more preferable.

Examples of the metal atom represented by B in general formula (1) include lead, tin, zinc, titanium, antimony, bismuth, nickel, iron, cobalt, silver, copper, gallium, germanium, magnesium, calcium, indium, aluminum, manganese, chromium, molybdenum, europium, and the like. In the perovskite compound (1), the metal atom represented by B may be only one kind of metal atom or two or more kinds of metal atoms. The metal atom represented by B is preferably lead atom from the viewpoint of improving the light-absorbing property and the charge-generating property of the light absorption layer 6.

In general formula (1), examples of the halogen atoms represented by X includes fluorine atom, chlorine atom, bromine atom, iodine atom, and the like. In the perovskite compound (1), the halogen atom represented by X may be only one kind of halogen atom or two or more kinds of halogen atoms. The halogen atom represented by X is preferably iodine atom from the viewpoint of narrowing an energy band gap of the perovskite compound (1). Specifically, it is preferable that at least one of the three Xs represents iodine atom, and it is more preferable that all of the three Xs represent iodine atom.

The perovskite compound (1) is preferably a compound represented by general formula “CH₃NH₃PbX₃ (wherein X represents a halogen atom)”, more preferably CH₃NH₃PbI₃. When the compound represented by general formula “CH₃NH₃PbX₃” (in particular, CH₃NH₃PbI₃) is used as the perovskite compound (1), electrons and holes can be more efficiently generated in the light absorption layer 6, and as a result, the photoelectric conversion efficiency of the photoelectric conversion element 1 can be further improved.

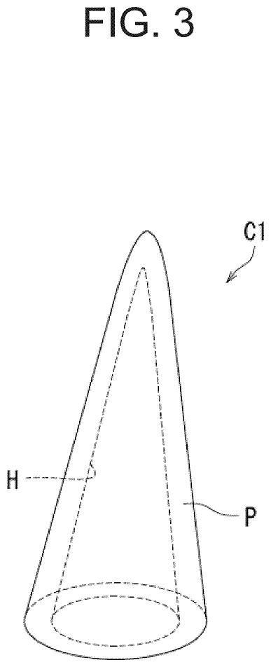

The structure of the crystal (α) will be explained below in detail on the basis of the figures. FIG. 3 illustrates a crystal (α) C1 as an example of the crystal (α). The crystal (α) C1 has a hollow conical shape. The crystal (α) C1 has a perovskite layer P containing the perovskite compound. The crystal (α) C1 has a hollow portion H formed inside the perovskite layer P. The hollow portion H does not penetrate the perovskite layer P at the apex of the crystal (α) C1.

Preferably, the perovskite layer P has a thickness of 50 nm or larger to 300 nm or smaller. When the thickness of the perovskite layer P is 50 nm or larger to 300 nm or smaller, the photoelectric conversion efficiency of the crystal (α) can be further improved. If the thickness of the perovskite layer P is smaller than 50 nm, there is a possibility that a rigidity of the crystal (α) decreases and a mechanical strength decreases. If the thickness of the perovskite layer P is larger than 300 nm, there is a tendency that a light confining effect attributed to the crystal (α) described later is hardly obtained.

The crystal (α) exhibits an excellent photoelectric conversion efficiency compared to crystals of general perovskite compounds because of the conical shape or elliptical conical shape. The reasons for this will be explained below. Crystals of general perovskite compounds have a planar crystal structure. In contrast, the crystal (α) has the conical or elliptical conical shape. Thus, the crystal (α) has a wide effective light reception area. Preferably, the crystal (α) has a hollow conical shape or a hollow elliptical conical shape. Light incident on the hollow conical or ellipsoidal conical crystal (α) is confined in the perovskite layer P and is difficult to leak out. Thus, the crystal (α) can efficiently absorb light. Furthermore, the crystal (α) has a preferable band structure as described below.

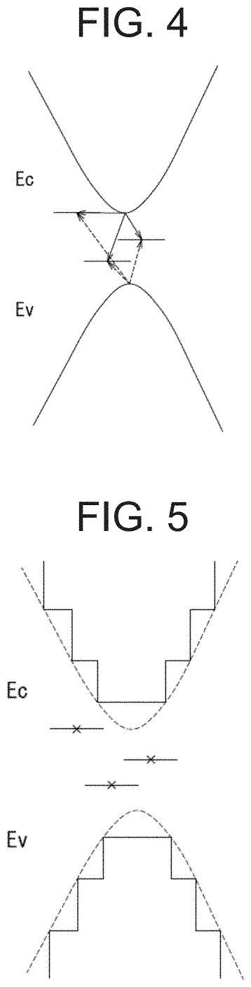

FIG. 4 illustrates a band structure of a crystal of a general perovskite compound. As illustrated in FIG. 4, in the crystal of the general perovskite compound, there are defect levels in band gaps, and some of photoexcited carriers (electrons or holes) generated by a photoelectric effect are trapped by the defect levels, so that the photoelectric conversion efficiency decreases. In contrast, in the crystal (α), discretized levels are formed by a quantum confinement effect (quantum well construction), as illustrated in FIG. 5. Specifically, the band structure indicated by a solid line in FIG. 5 refers to the band structure of the crystal (α). The band structure indicated by a dotted line in FIG. 5 refers to a band structure of a general perovskite compound crystal. As illustrated in FIG. 5, the band structure of the crystal (α) has the discretized levels, so that the photoexcited carriers generated by the photoelectric effect are hardly trapped by the defective levels. Thereby, the crystal (α) can exhibit an excellent photoelectric conversion efficiency.

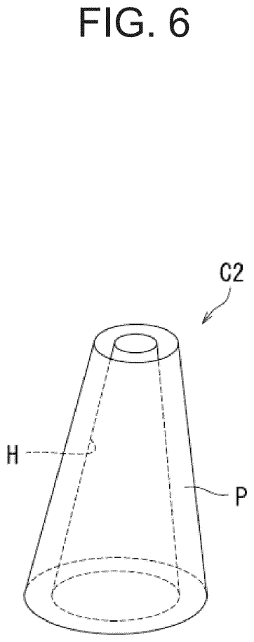

FIG. 6 illustrates a crystal (α) C2 as an example of the crystal (α), different from that in FIG. 3. The crystal (α) C2 has a hollow conical shape. The crystal (α) C2 has a perovskite layer P containing the perovskite compound. The crystal (α) C2 has a hollow portion H formed inside the perovskite layer P. In the crystal (α) C2, the hollow portion H penetrates the perovskite layer P at the apex of the crystal (α) C2. Thus, the crystal (α) C2 has a tube structure.

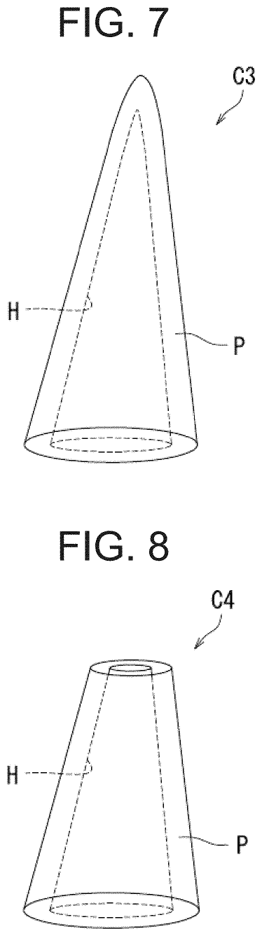

FIG. 7 illustrates a crystal (α) C3 as an example of the crystal (α), different from those in FIG. 3 and FIG. 6. The crystal (α) C3 has a hollow elliptical conical shape. The crystal (α) C3 has a perovskite layer P containing the perovskite compound. The crystal (α) C3 has a hollow portion H formed inside the perovskite layer P. The hollow portion H does not penetrate the perovskite layer P at the apex of the crystal (α) C3.

FIG. 8 illustrates a crystal (α) C4 as an example of the crystal (α), different from those in FIG. 3, FIG. 6, and FIG. 7. The crystal (α) C4 has a hollow elliptical conical shape. The crystal (α) C4 has a perovskite layer P containing the perovskite compound. The crystal (α) C4 has a hollow portion H formed inside the perovskite layer P. The hollow portion H penetrates the perovskite layer P at the apex of the crystal (α) C4. Thus, the crystal (α) C4 has a tube structure.

As described above, the crystal (α) has the conical or elliptical conical shape. The crystal (α) preferably has a hollow conical or hollow elliptical conical shape, and among them, the hollow elliptical conical shape is more preferable. The hollow elliptical conical crystal (α) has a wider effective light reception area and can absorb light more efficiently compared to the hollow conical crystal (α). Thus, the hollow elliptical conical crystal (α) is superior to the hollow conical crystal (α) in the photoelectric conversion efficiency.

At the apex of the hollow conical or hollow elliptical conical crystal (α), the hollow portion may or may not penetrate the perovskite layer. That means, the hollow conical or hollow elliptical conical crystal (α) may or may not have a tube structure.

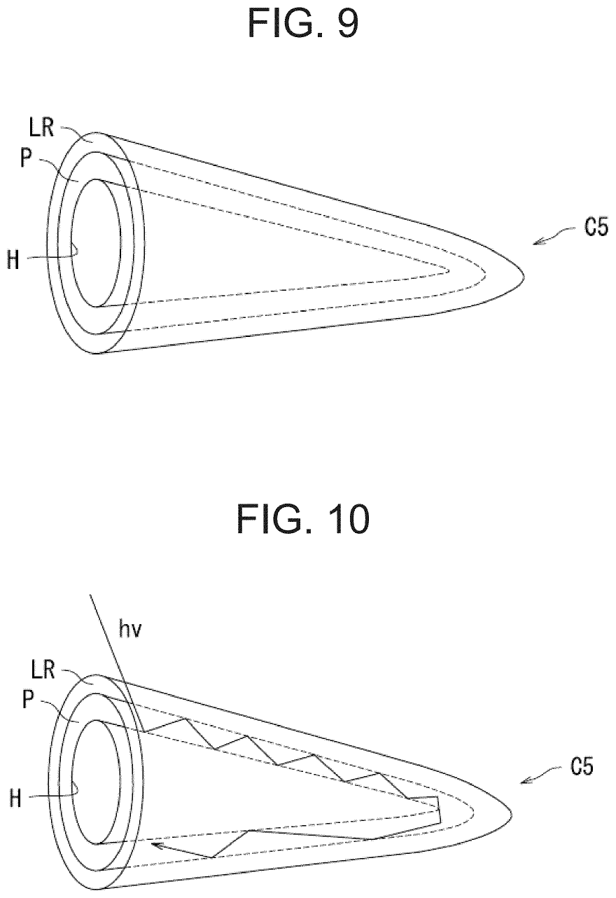

FIG. 9 illustrates a crystal (α) C5 as an example of the crystal (α), different from those in FIG. 3, and FIG. 6 to FIG. 8. The crystal (α) C5 has a hollow elliptical conical shape. The crystal (α) C5 has a perovskite layer P containing the perovskite compound, and a first coating layer LR for coating an outer periphery of the perovskite layer P. The crystal (α) C5 has a hollow portion H formed inside the perovskite layer P. The hollow portion H does not penetrate the perovskite layer P at the apex of the crystal (α) C5. The first coating layer LR contains a low refractive index material having a lower refractive index than of the perovskite compound. A typical refractive index of perovskite compounds is about 2.40.

Preferably, the first coating layer LR has a thickness of 100 nm or larger to 300 nm or smaller. The first coating layer LR may have different thicknesses between the apex and the bottom face of the crystal (α) C5. For example, it is preferable that the first coating layer LR is relatively thin at the apex of the crystal (α) C5 and relatively thick at the bottom face of the crystal (α) C5. In this case, the thickness of the first coating layer LR is represented by the thickness measured at the apex of the crystal (α) C5.

The first coating layer LR further improves a photoelectric conversion efficiency of the crystal (α) C5, for the following reasons. FIG. 10 illustrates an optical path of a photon hv incident on the crystal (α) C5. As illustrated in FIG. 10, the crystal (α) C5 has a structure similar to that of an optical fiber. Specifically, once the photon hv enters the crystal (α) C5, the photon hv is reflected on an interface between the perovskite layer P and the first coating layer LR. Thereby, the photon hv is confined in the crystal (α) C5. As a result, in the crystal (α) C5, sufficient photoexcited carriers can be extracted. As described above, the crystal (α) C5 exhibits a further excellent photoelectric conversion efficiency by the first coating layer LR.

The low refractive index material can be exemplified by a resin. The resin to be used as the low refractive index material is preferably a polyvinyl butyral resin or a cellulose resin (particularly, ethylcellulose resin). Typical refractive indices of the polyvinyl butyral resin and the cellulose resin are 1.50 and 1.47 respectively. In order to form the first coating layer LR, a resin solution containing a resin as the low refractive index material and a solvent should be applied on the light absorption layer 6 when forming the light absorption layer 6. At this time, the solution containing the resin as the low refractive index material preferably has a relatively low viscosity. The solvent for dissolving the resin as the low refractive index material is preferably a solvent (e.g. toluene, chlorobenzene, etc.) that hardly affects the crystal structure of the perovskite compound. In view of the above description, it is preferable that the resin as the low refractive index material is soluble in a solvent that hardly affects the crystal structure of the perovskite compound, and exhibits a relatively low viscosity when dissolved in such a solvent. The polyvinyl butyral resin or the cellulose resin satisfies the aforementioned conditions, and is therefore suitable for the resin to be used as a low refractive index material.

In the crystal (α) C5 illustrated in FIG. 9, the first coating layer LR coats the outer periphery of the perovskite layer P. However, in the first embodiment, the layer structure in which the crystal (α) includes the first coating layer is not limited to the aforementioned layer structure. Specifically, the first coating layer only needs to be laminated on the outer peripheral side of the perovskite layer and need not directly coat the outer periphery of the perovskite layer. That means, there may be another layer (e.g. a water-repellent resin layer described later) between the first coating layer and the perovskite layer. In addition, the first coating layer may be further laminated on the inner peripheral side of the perovskite layer.

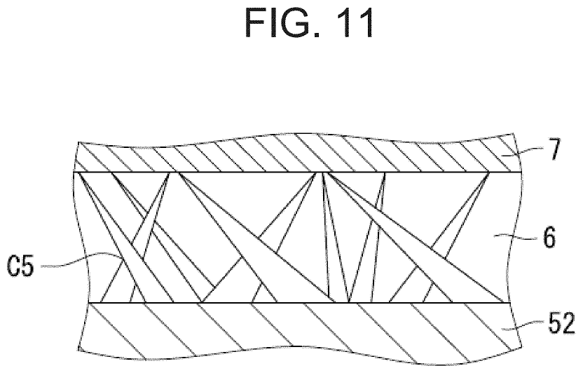

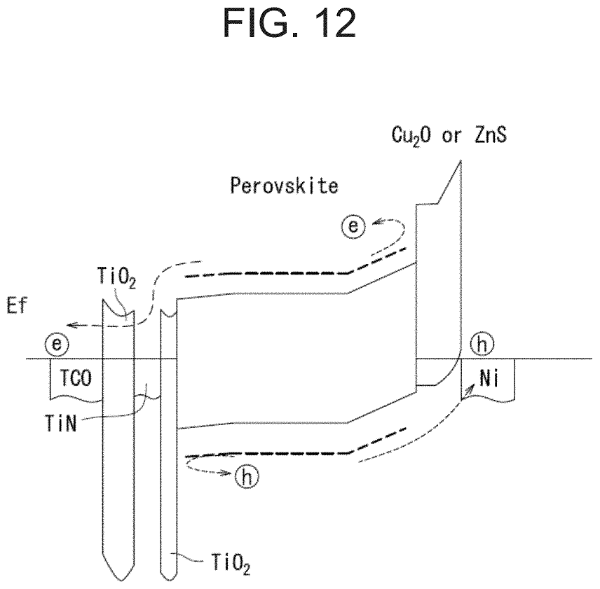

FIG. 11 is an enlarged view illustrating the light absorption layer 6 containing the crystal (α) C5. As illustrated in FIG. 11, it is preferable that, in the light absorption layer 6, the apex of the crystal (α) C5 is positioned on the backside electrode 8-side face (interface between the light absorption layer 6 and the hole transport layer 7), and the bottom face of the crystal (α) C5 is positioned on the surface electrode 3-side face (interface between the light absorption layer 6 and the porous titanium oxide layer 52). When the crystal (α) C5 is oriented as illustrated in FIG. 11, the photoelectric conversion efficiency of the photoelectric conversion element 1 can be further improved for the following reasons. FIG. 12 illustrates a band structure of the light absorption layer 6 in FIG. 11. In FIG. 12, the “Perovskite” represents the light absorption layer 6. The “TCO, TiO₂, TiN and TiO₂” on the left of the “Perovskite” represent an example of a composition of the electron transport layer 4 and the surface electrode 3. The “Cu₂O or ZnS” and the “Ni” on the right of the “Perovskite” represent an example of the composition of the hole transport layer 7 and an example of the composition of the backside electrode 8. As illustrated in FIG. 12, in the light absorption layer 6 of FIG. 11, a quantum level is formed in a conduction electron band and a valence band of the crystal (α) C5. As a result, in the light absorption layer 6 of FIG. 11, the photoexcited carriers are extracted from the surface electrode 3 side and the backside electrode 8 side via the quantum level of the conduction electron band or the quantum level of the valence band respectively. That means, in the light absorption layer 6 of FIG. 11, the photoexcited carriers are extracted via the quantum level. Thus, when extracting the photoexcited carriers as described above, the photoexcited carriers are unlikely to be trapped by a combination level constituting the interface of the light absorption layer 6 in FIG. 11. As described above, the crystal (α) C5 is oriented as illustrated in FIG. 11, so that the photoelectric conversion efficiency of the photoelectric conversion element 1 can be further improved.

In FIG. 11, the bottom face of the crystal (α) C5 may be fused with the bottom face of another crystal (α) C5 via the first coating layer LR. In other words, the first coating layer LR may also functionally serve as a binder for fusing the plurality of crystals (α) C5.

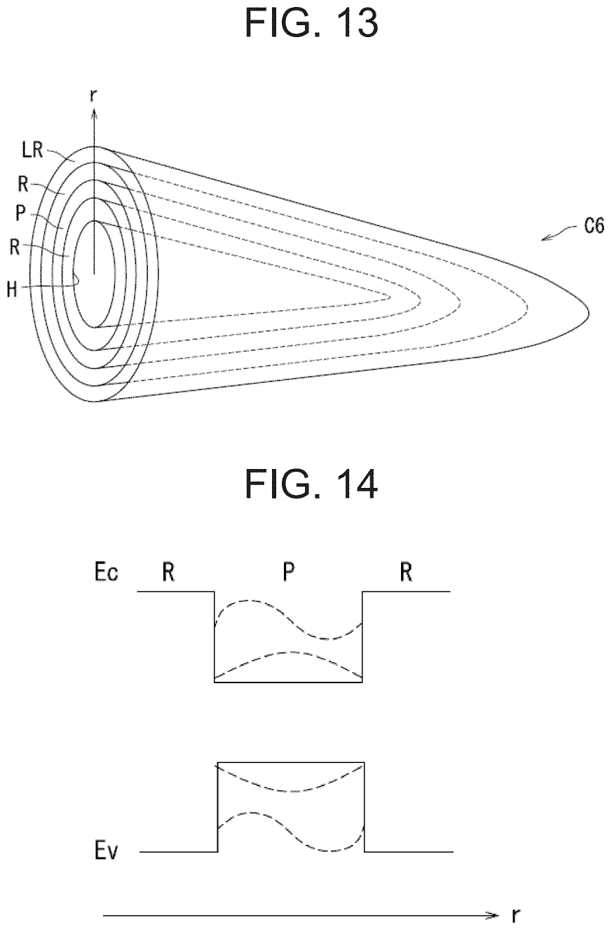

FIG. 13 illustrates a crystal (α) C6 as an example of the crystal (α), different from those in FIG. 3, and FIG. 6 to FIG. 9. The crystal (α) C6 has a hollow elliptical conical shape. The crystal (α) C6 has a perovskite layer P containing the perovskite compound, a second coating layer R for coating the inner and outer peripheries of the perovskite layer P, and a first coating layer LR that is laminated on the outer peripheral side of the perovskite layer P. The first coating layer LR coats the outer periphery of the perovskite layer P via the second coating layer R. The first coating layer LR contains a low refractive index material having a lower refractive index than of the perovskite compound. The second coating layer R contains a water-repellent resin. Examples of the water-repellent resin include a silicone resin and a fluororesin. Once the aforementioned resin molecule bonds to the surface of the perovskite layer P, the second coating layer R having a film thickness of about several angstroms is formed.

The perovskite layer P tends to decrease in the photoelectric conversion efficiency by influence of moisture. The second coating layer R coats the inner and outer peripheries of the perovskite layer P to restrain moisture from entering the perovskite layer P. As a result, the crystal (α) C6 can maintain the photoelectric conversion efficiency for a long period. The second coating layer R further improves the photoelectric conversion efficiency of the crystal (α) C6, for the following reasons. FIG. 14 illustrates a band structure of the crystal (α) C6 in a radius vector direction r. In FIG. 14, the dotted line indicates the band structure in the absence of the second coating layer R. In FIG. 14, the solid line indicates the band structure in the presence of the second coating layer R. As illustrated in FIG. 14, the presence of the second coating layer R makes it possible to increase a band offset on the interface of the perovskite layer P, so that the effect of the quantum well can be enhanced. Specifically, when there is the second coating layer R as a barrier layer inside and outside the perovskite layer P in the radius vector direction r, recombination of the photoexcited carriers at the defect level can be prevented on the interface of the perovskite layer P in the radius vector direction r.

In the first embodiment, the layer structure in which the crystal (α) includes the second coating layer may differ from that of the crystal (α) C6. For example, the second coating layer may coat only the outer periphery or the inner periphery of the perovskite layer. The crystal (α) including the second coating layer does not have to include the first coating layer.

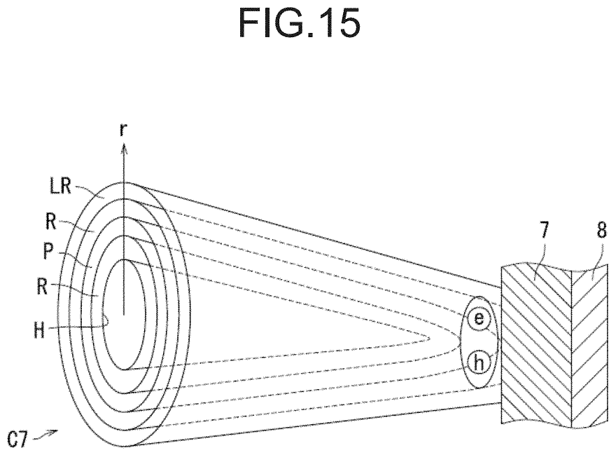

FIG. 15 illustrates a crystal (α) C7 that is an example of a more preferable aspect of the crystal (α) C6 in FIG. 13. The crystal (α) C7 has a hollow elliptical conical shape. The crystal (α) C7 has a perovskite layer P containing the perovskite compound, a second coating layer R for coating the inner and outer peripheries of the perovskite layer P, and a first coating layer LR that is laminated on the outer peripheral side of the perovskite layer P. The first coating layer LR coats the outer periphery of the perovskite layer P via the second coating layer R. The first coating layer LR contains a low refractive index material having a lower refractive index than of the perovskite compound. The second coating layer R contains a water-repellent resin. The perovskite layer P is exposed at the apex of the crystal (α) C7.

As will be described below, the surface electrode 3, the light absorption layer 6, and the backside electrode 8 are essential constituents for the photoelectric conversion element 1. However, when the light absorption layer 6 contains the crystal (α) C7, the photoelectric conversion element 1 preferably further includes the hole transport layer 7 disposed between the backside electrode 8 and the light absorption layer 6. In this case, it is preferable that the hole transport layer 7 contains an inorganic material having a band gap of 2 eV or higher and an ionization potential of −5.3 eV or higher. Since the band gap of the perovskite layer P is about 1.5 eV, the hole transport layer 7 preferably has a band gap of 1.5 eV or higher. The ionization potential of the perovskite layer P is positioned around −5.3 eV. From the viewpoint of a hole conduction, if the ionization potential of the hole transport layer 7 is −5.3 eV or higher, the holes can be conducted through the hole transport layer 7 from the perovskite layer P without hindrance. Preferably, the crystal (α) C7 abuts on the hole transport layer 7 at the apex. When the photoelectric conversion element 1 has the aforementioned configuration, the photoelectric conversion efficiency can be further improved for the following reasons.

In the perovskite layer P, photoexcited carriers are generated at the apex that is a spatially limited region in some cases. In this case, the generated photoexcited carriers form excitons by strong Coulomb interaction. As a result, an extraction efficiency of the photoexcited carriers from the light absorption layer 6 is lowered. In contrast, when the photoelectric conversion element 1 has the aforementioned configuration, the hole transport layer 7 functionally serves as an interfacial polarization layer for restraining exciton generation at the apex of the crystal (α) C7. Specifically, the hole transport layer 7 restrains the recombination of the electrons and the holes on the interface between the perovskite layer P and the hole transport layer 7 by blocking the electrons formed on the perovskite layer P. As a result, the photoelectric conversion efficiency of the photoelectric conversion element 1 can be further improved.

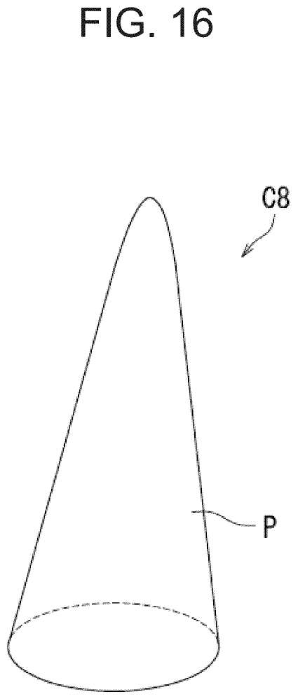

FIG. 16 illustrates a crystal (α) C8 as an example of the crystal (α), different from those in FIG. 3, FIG. 6 to FIG. 9, and FIG. 13. The crystal (α) C8 has a solid conical shape. The crystal (α) C8 has a perovskite layer P containing the perovskite compound. The crystal (α) C8 differs from the crystal (α) C1 in FIG. 3 in that the crystal (α) C8 has a solid structure. Since the crystal (α) C8 has a wide effective light reception area, and therefore exhibits a superior photoelectric conversion efficiency to general perovskite compound crystals having a planar crystal structure.

As described above, the crystal (α) has been explained. Other configurations of the photoelectric conversion element 1 will be explained below.

Substrate

Examples of the shape of the substrate 2 include a flat plate shape, a film shape, or a cylindrical shape. When the substrate 2-side face of the photoelectric conversion element 1 is irradiated with light, the substrate 2 is transparent. In this case, examples of a material for the substrate 2 include transparent glass (more specifically, soda lime glass, alkali-free glass, etc.) and a heat-resistant transparent resin. When the backside electrode 8-side face of the photoelectric conversion element 1 is irradiated with light, the substrate 2 may be opaque. In this case, examples of the material for the substrate 2 include aluminum, nickel, chromium, magnesium, iron, tin, titanium, gold, silver, copper, tungsten, alloys thereof (e.g., stainless steel), and ceramic.

Surface Electrode

The surface electrode 3 corresponds to a cathode of the photoelectric conversion element 1. Examples of a material constituting the surface electrode 3 include a transparent conductive material (in particular, transparent conductive oxide (TCO)) and an opaque conductive material. Examples of the transparent conductive material include copper iodide (CuI), indium tin oxide (ITO), tin oxide (SnO₂), fluorine-doped tin oxide (FTO), aluminum-doped zinc oxide (AZO), indium zinc oxide (IZO), gallium-doped zinc oxide (GZO), and the like. Examples of the opaque conductive material include sodium, sodium-potassium alloy, lithium, magnesium, aluminum, magnesium-silver mixture, magnesium-indium mixture, aluminum-lithium alloy, aluminum-aluminum oxide mixture (Al/Al₂O₃) and aluminum-lithium fluoride mixture (Al/LiF), and the like.

A film thickness of the surface electrode 3 is not particularly limited as long as the surface electrode 3 can exhibit desired properties (e.g. electron transportability and transparency).

Electron Transport Layer

The electron transport layer 4 transports electrons generated by photoexcitation in the light absorption layer 6, to the surface electrode 3. For this reason, it is preferable that the electron transport layer 4 contains a material that facilitates movement of the electrons generated in the light absorption layer 6 toward the surface electrode 3. In the photoelectric conversion element 1, the electron transport layer 4 contains titanium oxide. Specifically, the electron transport layer 4 includes the dense titanium oxide layer 51 having a relatively low porosity, and the porous titanium oxide layer 52 that is a porous layer having a higher porosity than of the dense titanium oxide layer 51. A content ratio of titanium oxide in the electron transport layer 4 is e.g. 95% by mass or higher, preferably 100% by mass. The dense titanium oxide layer 51 and the porous titanium oxide layer 52 will be explained below.

Dense Titanium Oxide Layer

Since the dense titanium oxide layer 51 has a low porosity, the light absorbing material (perovskite compound) used for forming the light absorption layer 6 hardly penetrates into the layer during production of the photoelectric conversion element 1. Thus, the dense titanium oxide layer 51 included in the photoelectric conversion element 1 restrains contact between the light absorbing material and the surface electrode 3. In addition, the dense titanium oxide layer 51 included in the photoelectric conversion element 1 restrains contact between the surface electrode 3 and the backside electrode 8 that decreases an electromotive force. A film thickness of the dense titanium oxide layer 51 is preferably 5 nm or larger to 200 nm or smaller, more preferably 10 nm or larger to 100 nm or smaller.

Porous Titanium Oxide Layer

Since the porous titanium oxide layer 52 has a high porosity, the light absorbing material used for forming the light absorption layer 6 easily penetrates into pores in the layer during production of the photoelectric conversion element 1. Thus, the porous titanium oxide layer 52 included in the photoelectric conversion element 1 makes it possible to increase the contact area between the light absorption layer 6 and the electron transport layer 4. Thereby, the electrons generated by photoexcitation in the light absorption layer 6 can be efficiently transferred to the electron transport layer 4. A film thickness of the porous titanium oxide layer 52 is preferably 100 nm or larger to 2,0000 nm or smaller, more preferably 200 nm or larger to 1,500 nm or smaller.

Light Absorption Layer

The light absorption layer 6 contains the crystal (α), and absorbs light incident on the photoelectric conversion element 1 to generate electrons and holes. Specifically, once light enters the light absorption layer 6, low-energy electrons contained in the crystal (α) are photoexcited, so that high-energy electrons and holes are generated. The generated electrons move to the electron transport layer 4. The generated holes move to the hole transport layer 7. This movement of the electrons and holes results in charge separation.

The light absorption layer 6 may be a layer consisting of only the crystal (α). The light absorption layer 6 may further contain other components (e.g. light absorbing materials other than the perovskite compound, a binder resin, etc.) in addition to the crystal (α). A total content ratio of the crystal (α) in the light absorption layer 6 is preferably 80% by mass or higher, more preferably 100% by mass.

Hole Transport Layer

The hole transport layer 7 captures the holes generated in the light absorption layer 6 and transports the holes to the backside electrode 8 as an anode. The hole transport layer 7 contains an inorganic material (hereinafter, referred to as an inorganic hole transporting material in some cases) as a main component.

Examples of the inorganic hole transporting material include carbon nanotube, Cu₂O, ZnS, NiO, copper thiocyanate (CuSCN), and the like. Examples of the carbon nanotube include a multi-walled carbon nanotube (MWCNT), a single-walled carbon nanotube (SWCNT), and the like. The inorganic hole transporting material is preferably Cu₂O, ZnS, or NiO.

The hole transport layer 7 may further contain an organic binder resin, a plasticizer, or the like, as necessary. On the other hand, the hole transport layer 7 may contain only the inorganic hole transporting material. A content ratio of the inorganic hole transporting material in the hole transport layer 7 is preferably 30% by mass or higher to 100% by mass or lower, more preferably 50% by mass or higher to 100% by mass or lower.

A film thickness of the hole transport layer 7 is preferably 20 nm or larger to 2,000 nm or smaller, more preferably 200 nm or larger to 600 nm or smaller. When the film thickness of the hole transport layer 7 is 20 nm or larger and 2,000 nm or smaller, the holes generated in the light absorption layer 6 can be smoothly and efficiently transferred to the backside electrode 8.

When the backside electrode 8-side face of the photoelectric conversion element 1 is irradiated with light, the hole transport layer 7 is preferably an amorphous layer from the viewpoint of ensuring transparency.

Backside Electrode

The backside electrode 8 corresponds to the anode of the photoelectric conversion element 1. Examples of a material constituting the backside electrode 8 include a metal, a transparent conductive inorganic material, a conductive fine particle, a conductive polymer (in particular, a transparent conductive polymer), and the like. Examples of the metal include gold, silver, platinum, and the like. Examples of the transparent conductive inorganic material include copper iodide (CuI), indium tin oxide (ITO), tin oxide (SnO₂), fluorine-doped tin oxide (FTO), aluminum-doped zinc oxide (AZO), indium zinc oxide (IZO), gallium-doped zinc oxide (GZO), and the like. Examples of the conductive fine particle include a silver nanowire, a carbon nanofiber, and the like. Examples of the transparent conductive polymer include a polymer containing a poly(3,4-ethylenedioxythiophene) and polystyrene sulfonic acid (PEDOT/PSS), and the like.

When light enters the photoelectric conversion element 1 from the backside electrode 8 side, the backside electrode 8 is preferably transparent or translucent, more preferably transparent, for allowing the incident light to reach the light absorption layer 6. A material constituting the transparent or translucent backside electrode 8 is preferably a transparent conductive inorganic material or a transparent conductive polymer. A film thickness of the backside electrode 8 is preferably 50 nm or larger to 1,000 nm or smaller, more preferably 100 nm or larger to 300 nm or smaller.

Others

As described above, the photoelectric conversion element 1 as an example of the photoelectric conversion element according to the first embodiment has been explained with reference to the figures. However, the photoelectric conversion element according to the first embodiment is not limited to the photoelectric conversion element 1, and, for example, the following points can be changed.

The photoelectric conversion element according to the first embodiment may further include a surface layer on the backside electrode. The surface layer restrains deterioration of the inside of the photoelectric conversion element due to moisture and oxygen in air. The surface layer protects the outer face from shocks and scratches when using the photoelectric conversion element. A material constituting the surface layer is preferably a material having a high gas barrier property. The surface layer can be formed using e.g. a resin composition, a shrink film, a wrap film, a clear paint, or the like. On the other hand, it is preferable that the photoelectric conversion element that is contained in a sealed container when used includes no surface layer.

When light enters the photoelectric conversion element from the surface layer side, the surface layer is preferably transparent or translucent, more preferably transparent.

The electron transport layer does not have to contain titanium oxide. For example, the electron transport layer may include a dense layer composed of a material other than titanium oxide, and a porous layer composed of a material other than titanium oxide. The electron transport layer may have a single-layer structure, or a multi-layer structure composed of three or more layers.

The photoelectric conversion element according to the first embodiment only needs to include the surface electrode, the light absorption layer, the backside electrode, and the hole transport layer, and need not include other components. That means, in the photoelectric conversion element, the surface electrode, the light absorption layer, the backside electrode, and the hole transport layer are essential constituents, and the other components are optional constituents. When the photoelectric conversion element according to the first embodiment includes a substrate, the substrate may be conductive. In this case, the substrate also functionally serves as the surface electrode.

Production Method for Photoelectric Conversion Element

An example of a production method for the photoelectric conversion element according to the first embodiment will be explained. The production method for the photoelectric conversion element includes a light absorption layer forming step for forming the light absorption layer between the surface electrode and the backside electrode, and a hole transport layer forming step for forming the hole transport layer between the backside electrode and the light absorption layer.

As an example of the production method for the photoelectric conversion element according to the first embodiment, a production method for the photoelectric conversion element 1 illustrated in FIG. 1 will be explained. The production method for the photoelectric conversion element 1 illustrated in FIG. 1 includes e.g. a laminate preparing step for preparing a laminate including the substrate 2 and the surface electrode 3, an electron transport layer forming step for forming the electron transport layer 4 containing an electron transporting material on the surface electrode 3 in the laminate, a light absorption layer forming step for forming the light absorption layer 6 on the electron transport layer 4, a hole transport layer forming step for forming the hole transport layer 7 by applying a hole transport layer coating liquid containing an inorganic hole transporting material on the light absorption layer 6, and a backside electrode forming step for forming the backside electrode 8 on the hole transport layer 7.

Laminate Preparing Step

In this step, a laminate including the substrate 2 and the surface electrode 3 is prepared. The laminate is obtained e.g. by forming the surface electrode 3 on the substrate 2. Examples of the method for forming the surface electrode 3 on the substrate 2 include a vacuum deposition method, a sputtering method, a plating method, and the like.

Electron Transport Layer Forming Step

In this step, the electron transport layer 4 is formed on the surface electrode 3 in the laminate. Specifically, this step includes a dense titanium oxide layer forming step and a porous titanium oxide layer forming step.

Dense Titanium Oxide Layer Forming Step

In this step, the dense titanium oxide layer 51 is formed on the surface electrode 3 in the laminate. A method for forming the dense titanium oxide layer 51 on the surface electrode 3 can be exemplified by a method in which a dense titanium oxide layer coating liquid containing a titanium chelate compound is applied on the surface electrode 3 and then sintered. Examples of the method of applying the dense titanium oxide layer coating liquid on the surface electrode 3 include a spin coating method, a screen printing method, a casting method, an immersion coating method, a roll coating method, a slot die method, a spray pyrolysis method, an aerosol deposition method, and the like. After sintering, preferably the formed dense titanium oxide layer 51 is immersed in a titanium tetrachloride aqueous solution. This treatment makes it possible to increase the denseness of the dense titanium oxide layer 51.

Examples of the solvent for the dense titanium oxide layer coating liquid include an alcohol (particularly, 1-butanol), and the like. Examples of the titanium chelate compound contained in the dense titanium oxide layer coating liquid include a compound having an acetoacetate chelate group, and a compound having a ß-diketone chelate group.

Example of the compound having the acetoacetate chelate group include, but are not particularly limited to, diisopropoxytitanium bis(methylacetoacetate), diisopropoxytitanium bis(ethylacetoacetate), diisopropoxytitanium bis(propylacetoacetate), diisopropoxytitanium bis(butylacetoacetate), dibutoxytitanium bis(methylacetoacetate), dibutoxytitanium bis(ethylacetoacetate), triisopropoxytitanium(methylacetoacetate), triisopropoxytitanium(ethylacetoacetate), tributoxytitanium(methylacetoacetate), tributoxytitanium(ethylacetoacetate), isopropoxytitanium tri(methylacetoacetate), isopropoxytitanium tri(ethylacetoacetate), isobutoxytitanium tri(methylacetoacetate), and isobutoxytitanium tri(ethylacetoacetate).

Examples of the compound having the ß-diketone chelate group include, but are not particularly limited to, diisopropoxytitanium bis(acetylacetonate), diisopropoxytitanium bis(2,4-heptanedionate), dibutoxytitanium bis(acetylacetonate), dibutoxytitanium bis(2,4-heptanedionate), triisopropoxytitanium(acetylacetonate), triisopropoxytitanium(2,4-heptanedionate), tributoxytitanium(acetylacetonate), tributoxytitanium(2,4-heptanedionate), isopropoxytitanium tri(acetylacetonate), isopropoxytitanium tri(2,4-heptanedionate), isobutoxytitanium tri(acetylacetonate), and isobutoxytitanium tri(2,4-heptanedionate).

The titanium chelate compound is preferably the compound having an acetoacetate chelate group, more preferably the diisopropoxytitanium bis(methylacetoacetate). As the titanium chelate compound, commercially available products such as “TYZOR (registered trademark) AA” series manufactured by DuPont de Nemours, Inc. may be used.

Porous Titanium Oxide Layer Forming Step

In this step, the porous titanium oxide layer 52 is formed on the dense titanium oxide layer 51. A method for forming the porous titanium oxide layer 52 can be exemplified by a method in which a porous titanium oxide layer coating liquid containing titanium oxide is applied on the dense titanium oxide layer 51 and then sintered. The porous titanium oxide layer coating liquid further contains e g a solvent and an organic binder. When the porous titanium oxide layer coating liquid contains an organic binder, the organic binder is removed by the sintering. Examples of the method of applying the porous titanium oxide layer coating liquid on the dense titanium oxide layer 51 include a spin coating method, a screen printing method, a casting method, an immersion coating method, a roll coating method, a slot die method, a spray pyrolysis method, an aerosol deposition method, and the like.

A pore diameter and a void ratio (porosity) of the porous titanium oxide layer 52 can be adjusted depending on e.g. a particle diameter of the titanium oxide particle contained in the porous titanium oxide layer coating liquid, and a type and a content of the organic binder.

Examples of the titanium oxide contained in the porous titanium oxide layer coating liquid include, but are not particularly limited to, an anatase type titanium oxide. The porous titanium oxide layer coating liquid can be prepared e.g. by dispersing titanium oxide particles (more specifically, “AEROXIDE (registered trademark) TiO₂ P25” manufactured by NIPPON AEROSIL CO., LTD., etc.) in an alcohol (e.g. ethanol, etc.). The porous titanium oxide layer coating liquid can be prepared e.g. by diluting a titanium oxide paste (more specifically, “PST-18NR” or the like manufactured by JGC Catalysts and Chemicals Ltd.) in an alcohol (e.g. ethanol or the like).

When the porous titanium oxide layer coating liquid contains an organic binder, the organic binder is preferably an ethyl cellulose or an acrylic resin. The acrylic resin is excellent in low-temperature decomposability, and even if the sintering is carried out at a low temperature, organic matters are unlikely to remain in the porous titanium oxide layer 52. The acrylic resin that decomposes at about 300° C. is preferable. Examples of the acrylic resin include a polymer of at least one (meth)acrylic monomer. Examples of the (meth)acrylic monomer include methyl(meth)acrylate, ethyl(meth)acrylate, propyl(meth)acrylate, n-butyl(meth)acrylate, tert-butyl(meth)acrylate, isobutyl(meth)acrylate, cyclohexyl(meth)acrylate, 2-ethylhexyl(meth)acrylate, isobornyl(meth)acrylate, n-stearyl(meth)acrylate, benzil(meth)acrylate, as well as a (meth)acrylic monomer having a polyoxyalkylene structure, and the like.

Light Absorption Layer Forming Step

In this step, the light absorption layer 6 is formed on the electron transport layer 4 (specifically, on the porous titanium oxide layer 52). This step may be performed in the atmosphere from the viewpoint of reducing the production cost. The method for forming the light absorption layer 6 on the electron transport layer 4 can be exemplified by a method including a crystal (α) layer forming step in which a porous layer (hereinafter referred to as a crystal (α) layer in some cases) containing the crystal (α) including the perovskite layer P is formed on the electron transport layer 4.

Crystal (α) Layer Forming Step

In this step, the crystal (α) layer containing the crystal (α) is formed on the electron transport layer 4 (specifically, on the porous titanium oxide layer 52). When the perovskite compound is the perovskite compound (1), the crystal (α) layer can be formed e.g. by the following one-step method or two-step method.

In the one-step method, a solution containing a compound represented by general formula “AX” (hereinafter referred to as a compound (AX)) and a solution containing a compound represented by general formula “BX₂” (hereinafter referred to as a compound (BX₂)) are mixed to obtain a mixture. A, B, and X in general formula “AX” and general formula “BX₂” are synonymous with A, B, and X respectively in general formula (1). This mixture is applied on the porous titanium oxide layer 52, and the formed liquid film is dried to form the crystal (α) layer containing the crystal (α) containing the perovskite compound (1) represented by general formula “ABX₃”. Examples of the method for applying the mixture on the porous titanium oxide layer 52 include an immersion coating method, a roll coating method, a spin coating method, a screen printing method, a slot die method, and the like.

In the two-step method, the solution containing the compound (BX₂) is applied on the porous titanium oxide layer 52 to form a liquid film. The solution containing the compound (AX) is applied on this liquid film to react the compound (BX₂) and the compound (AX) in the liquid film. Subsequently, the liquid film is dried to form the crystal (α) layer including the crystal (α) containing the perovskite compound (1) represented by general formula “ABX₃”. Examples of the method for applying the solution containing the compound (BX₂) on the porous titanium oxide layer 52 and the method for applying the solution containing the compound (AX) on the liquid film include an immersion coating method, a roll coating method, a spin coating method, a screen printing method, a slot die method, and the like.

In this step, the perovskite compound (1) can be grown into a conical or elliptical conical crystal (α) by adjusting the drying condition of the liquid film and generating a temperature difference between the lower layer and the surface of the liquid film in both the one-step method and the two-step method. Specifically, crystallization of the perovskite compound (1) is enhanced at a site with a high liquid temperature. Since the perovskite compound (1) generates latent heat in association with crystallization, the temperature rises on the surface of the formed perovskite compound (1) crystal. As described above, the perovskite compound (1) is crystallized on the lower layer of the liquid film by generating the temperature difference between the lower layer and the surface of the liquid film when drying the liquid film. Accordingly, a surface temperature of the crystal of the perovskite compound (1) increases. Then, the crystallization of the perovskite compound (1) proceeds in one direction from the lower layer of the liquid film toward the surface of the liquid film. As a result, the perovskite compound (1) forms the conical or elliptical conical crystal (α).

Examples of the method for generating the temperature difference between the lower layer and the surface of the liquid film include a humidity adjusting method, a pressure reducing method, and a nitrogen gas inflow rate adjusting method. Above all, the humidity adjusting method is preferable. The liquid film is dried in a relatively high humid environment, so that the solvent easily evaporate on the surface of the liquid film. Thereby, evaporation heat is generated on the surface of the liquid film, the surface temperature of the liquid film is lowered. As a result, the temperature difference is generated between the lower layer and the surface of the liquid film. When the humidity is adjusted in drying the liquid film, the specific humidity is preferably 40% RH or higher to 75% RH or lower. In particular, there is a tendency that a hollow conical crystal (α) is easily formed by adjusting the humidity to 40% RH or higher to 65% RH or lower when drying the liquid film. On the other hand, there is a tendency that a hollow elliptical conical crystal (α) is easily formed by adjusting the humidity to higher than 65% RH to 75% RH or lower when drying the liquid film.

Low Refractive Index Material Solution Applying Step

Preferably, the light absorption layer forming step further includes a low refractive index material solution applying step in which a low refractive index material solution containing a low refractive index material is applied on the formed crystal (α) layer after the crystal (α) layer forming step. Thereby, the first coating layer LR that is laminated on the periphery side of the perovskite layer P can be formed, similarly to the crystal (α) C5 illustrated in FIG. 9.

Examples of the low refractive index material contained in the low refractive index material solution include a polyvinyl butyral resin and a cellulose resin. As the solvent contained in the low refractive index material solution, a solvent that hardly affects the crystal structure of the perovskite compound is preferable. Specific examples of the solvent include toluene, chlorobenzene, ethyl acetate, diethyl ether, and the like, and above all, toluene or chlorobenzene is preferable.

Examples of the method for applying the low refractive index material solution on the crystal (α) layer include an immersion coating method, a roll coating method, a spin coating method, a screen printing method, a slot die method, and the like, and above all, the screen printing method is preferable.

A content ratio of the low refractive index material in the low refractive index material solution is preferably 0.1% by mass or higher to 5.0% by mass or lower, more preferably 1.0% by mass or higher to 2.0% by mass or lower. When the content ratio of the low refractive index material is 0.1% by mass or higher, a sufficient amount of the low refractive index material can penetrate the crystal (α) layer. When the content ratio of the low refractive index material is 5.0% by mass or lower, the viscosity of the low refractive index material solution is moderately decreased, so that the low refractive index material solution can easily penetrate into the crystal (α) layer.

Water-Repellent Resin Solution Applying Step

Preferably, the light absorption layer forming step further includes a water-repellent resin solution applying step in which a water-repellent resin solution containing a water-repellent resin is applied on the formed crystal (α) layer, after the crystal (α) layer forming step and before the low refractive index material solution applying step. Thereby, the second coating layer R for coating the inner and outer peripheries of the perovskite layer P can be formed, as illustrated in the crystal (α) C6 of FIG. 13.

Etching Step

Preferably, the light absorption layer forming step further includes an etching step in which the surface of the formed light absorption layer 6 is etched (reverse sputtering) as the last step. Thereby, the perovskite layer P can be exposed at the apex of the crystal (α) C7, as illustrated in the crystal (α) C7 of FIG. 15.

Hole Transport Layer Forming Step

In this step, the hole transport layer 7 is formed by applying a hole transport layer coating liquid containing an inorganic hole transporting material on the light absorption layer 6. The hole transport layer coating liquid contains e.g. an inorganic hole transporting material and an organic solvent. The organic solvent for the hole transport layer coating liquid is not particularly limited, but for example, an alcohol solvent (in particular, isopropyl alcohol) or the like can be used. In addition, chlorobenzene or toluene may be used as an organic solvent for the hole transport layer coating liquid to facilitate preservation of the crystal structure of the perovskite compound in the light absorption layer 6 The content ratio of the inorganic hole transporting material in the hole transport layer coating liquid is e.g. 0.5% by mass or higher to 5 mass % or lower.

Preferably, the hole transport layer coating liquid further contains a dispersant in addition to the inorganic hole transporting material and the organic solvent. A content ratio of the dispersant in the hole transport layer coating liquid is e.g. 0.5% by mass or higher to 5 mass % or lower.

Examples of the method for applying the hole transport layer coating liquid includes an immersion coating method, a spray coating method, a slide hopper coating method, a spin coating method, and the like.

Backside Electrode Forming Step

In this step, the backside electrode 8 is formed on the hole transport layer 7. The method for forming the backside electrode 8 on the hole transport layer 7 is not particularly limited, and the same method as the surface electrode 3 forming method (e.g. a vacuum deposition method, a sputtering method, and a plating method, etc.) can be used.

Others

As described above, the production method for the photoelectric conversion element 1 in FIG. 1 has been explained as an example of the production method for the photoelectric conversion element according to the first embodiment. However, the aforementioned production method is not limited to the aforementioned production method, and, for example, the following points can be changed.

The aforementioned production method may further include a surface layer forming step for forming a surface layer on the backside electrode. In the electron transport layer forming step, the electron transport layer may be formed by a method other than the aforementioned dense titanium oxide layer forming step and porous titanium oxide layer forming step.

In the aforementioned production method, the light absorption layer can be formed by a coating step under the atmosphere, and therefore a photoelectric conversion element can be produced at a low cost. The crystal (α) can be produced more stably than the crystal of the perovskite compound having a plate-like crystal structure. Thus, the aforementioned production method is excellent in yield. Furthermore, the photoelectric conversion element obtained by the aforementioned production method is excellent in photoelectric conversion efficiency.

### Second Embodiment: Solar Battery Module

A solar battery module according to the second embodiment includes a plurality of photoelectric conversion elements connected in series. The photoelectric conversion element refers to the photoelectric conversion element according to the first embodiment. The solar battery module according to the second embodiment includes the photoelectric conversion element according to the first embodiment, and is therefore excellent in the photoelectric conversion efficiency. In particular, the solar battery module according to the second embodiment functionally serves as a solar battery module excellent in the photoelectric conversion efficiency even when using a flexible substrate.

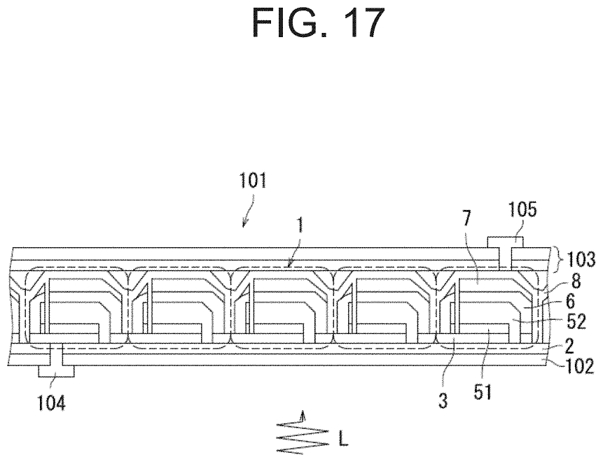

FIG. 17 illustrates a solar battery module 101 as an example of the solar battery module according to the second embodiment. The solar battery module 101 includes a surface cover layer 102 and a backside cover layer 103 that are opposed to each other, a plurality of photoelectric conversion elements 1 disposed between the surface cover layer 102 and the backside cover layer 103, a surface collecting electrode 104, and a backside collecting electrode 105. The plurality of photoelectric conversion elements 1 are connected in series. Light L enters the solar battery module 101 from a surface side.

### Example

The present invention will be further explained below with reference to Example. However, the present invention is not limited to Example.

Production of Photoelectric Conversion Element

Photoelectric conversion elements of Example and Comparative Example were produced by the following methods.

### Comparative Example

Laminate Preparing Step

A transparent glass plate (manufactured by Sigma-Aldrich Co. LLC, film thickness: 2.2 mm) deposited with a fluorine-doped tin oxide was cut into pieces of 25 mm in width and 25 mm in length. Thereby, a laminate including a substrate (transparent glass plate) and a surface electrode (film deposited with the fluorine-doped tin oxide) was prepared. This laminate was subjected to ultrasonic cleaning in ethanol (1 hour) and UV cleaning (30 minutes).

Dense Titanium Oxide Layer Forming Step

A 1-butanol solution (manufactured by Sigma-Aldrich Co. LLC) containing 75% by mass of diisopropoxytitanium bis(acetylacetonate) as a titanium chelate compound was diluted with 1-butanol. Thereby, a dense titanium oxide layer coating liquid in which a concentration of the titanium chelate compound was 0.02 mol/L was prepared. The dense titanium oxide layer coating liquid was applied on the surface electrode in the aforementioned laminate by a spin coating method, which was heated at 450° C. for 15 minutes. Thereby, a dense titanium oxide layer having a film thickness of 50 nm was formed on the surface electrode.

Porous Titanium Oxide Layer Forming Step

1 g of titanium oxide paste (“PST-18NR” manufactured by JGC Catalysts and Chemicals Ltd.) containing titanium oxide and ethanol was diluted with 2.5 g of ethanol to prepare a porous titanium oxide layer coating liquid. The porous titanium oxide layer coating liquid was applied on the aforementioned dense titanium oxide layer by the spin coating method, which was subsequently sintered at 450° C. for 1 hour. Thereby, a porous titanium oxide layer having a film thickness of 300 nm was formed on the dense titanium oxide layer.

Light Absorption Layer Forming Step

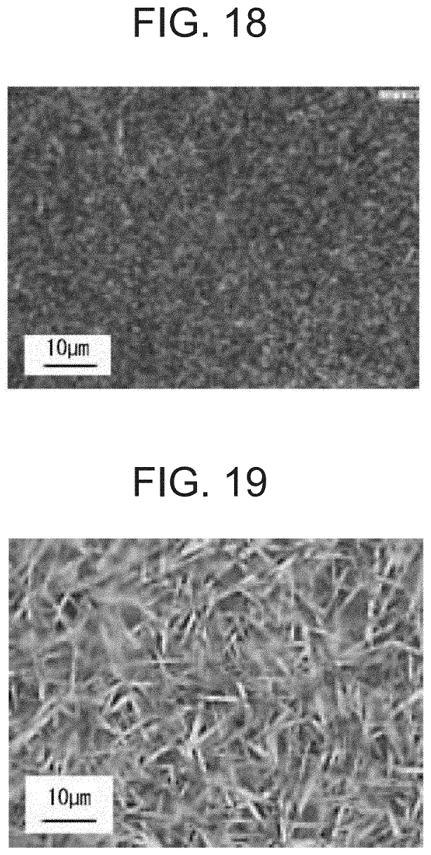

A light absorption layer was formed on the aforementioned porous titanium oxide layer by the following method. 922 mg of PbI₂ (manufactured by Tokyo Chemical Industry Co., Ltd.) and 318 mg of CH₃NH₃I (manufactured by Tokyo Chemical Industry Co., Ltd.) were heated and dissolved in 1.076 ml of N,N-dimethylformamide (DMF) (molar ratio of PbI₂CH₃NH₃I=1:1). Thereby, a mixture A having a solid content of 55% by mass was prepared. This mixture A was applied on the aforementioned porous titanium oxide layer by screen printing. A few drops of toluene were dripped to a liquid film immediately after the application, and then the color of the liquid film changed from yellow to black. Thereby, it was confirmed that the perovskite compound (CH₃NH₃PbI₃) was formed. Subsequently, the liquid film was dried at a humidity of 35% RH and at 100° C. for 60 minutes. Thereby, a light absorption layer having a film thickness of 500 nm was formed on the porous titanium oxide layer. The surface of the light absorption layer was observed with an optical microscope, and then it was confirmed that the light absorption layer was formed from perovskite compound crystals having a plate-like crystal structure (FIG. 18).

Hole Transport Layer Forming Step

0.2 g of multi-walled type carbon nanotube (MWCNT) (manufactured by Sigma-Aldrich Co. LLC) and 0.2 g of dispersant were dispersed in 12.21 mL of isopropyl alcohol. Thereby, a hole transport layer coating liquid was prepared. The hole transport layer coating liquid was applied on the aforementioned light absorption layer using a spin coating method. Then, the hole transport layer coating liquid after application was dried at 100° C. for 30 minutes to remove the organic solvent (isopropyl alcohol). Thereby, a hole transport layer having a film thickness of 500 nm was formed on the aforementioned light absorption layer.

Backside Electrode Forming Step

A gold deposition film having a thickness of 150 nm, a width of 25 mm and a length of 25 mm was formed as an anode on the aforementioned hole transport layer by a vacuum deposition method. Thereby, a photoelectric conversion element of Comparative Example was obtained, which included a substrate, a surface electrode, an electron transport layer (specifically, dense titanium oxide layer and porous titanium oxide layer), a light absorption layer, a hole transport layer, and a backside electrode. The light absorption layer contained a perovskite compound crystal having a plate-like crystal structure.

The photoelectric conversion element of Example was produced by the same method as in Comparative Example except that the following points were changed.

### Example

In production of the photoelectric conversion element of Example, a light absorption layer was formed by the following method. 922 mg of PbI₂ (manufactured by Tokyo Chemical Industry Co., Ltd.) and 318 mg of CH₃NH₃I (manufactured by Tokyo Chemical Industry Co., Ltd.) were heated and dissolved in 1.076 ml of N,N-dimethylformamide (DMF) (molar ratio of PbI₂CH₃NH₃I=1:1). Thereby, a mixture A having a solid content of 55% by mass was prepared. This mixture A was applied on the aforementioned porous titanium oxide layer by screen printing. A few drops of toluene were dripped to a liquid film immediately after the application, and then the color of the liquid film changed from yellow to black. Thereby, it was confirmed that the perovskite compound (CH₃NH₃PbI₃) was formed. Subsequently, the liquid film was dried at a humidity of 35% RH and at 100° C. for 60 minutes. Thereby, the crystal (α) layer having a film thickness of 500 nm was formed on the porous titanium oxide layer. The surface of the crystal (α) layer was observed with an optical microscope, and then it was confirmed that a porous layer was formed from conical or elliptical conical perovskite compound crystals (FIG. 19).

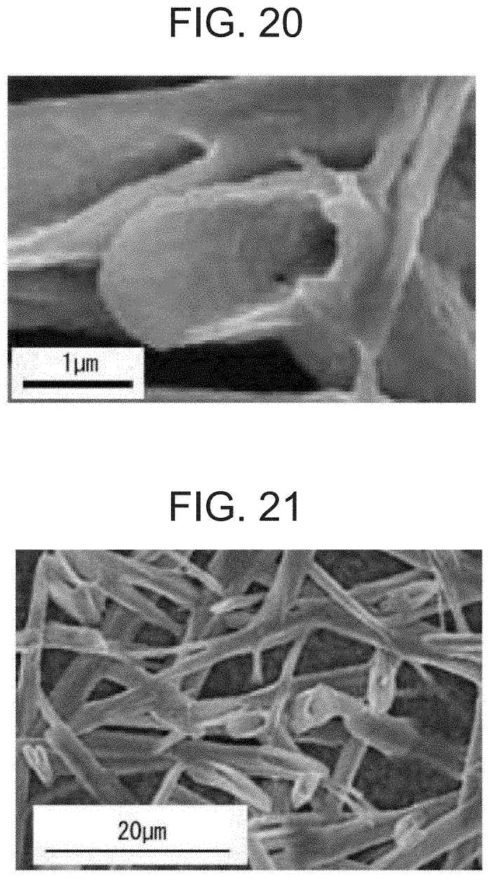

The cross section of the crystal (α) layer was observed using a scanning electron microscope (SEM, “Field Emission Scanning Electron Microscope S-4800” manufactured by Hitachi High-Tech Corporation.) with a magnification of 10,000 times, and SEM images were obtained (FIG. 20 and FIG. 21). As illustrated in FIG. 20 and FIG. 21, the crystal (α) contained in the crystal (α) layer had a hollow conical shape or a hollow elliptical conical shape.

0.1 g of a polyvinyl butyral resin (“S-LEC BL-S” manufactured by Sekisui Chemical Company, Limited) as a low refractive index material was dissolved in 5.68 ml of toluene as a solvent. The resulting low refractive index material solution was applied on the aforementioned crystal (α) layer using a screen printing method. Subsequently, a liquid film of the low refractive index material solution was naturally dried. Thereby, a light absorption layer was formed.

Evaluation

The photoelectric conversion elements of Example and Comparative Example were measured for each short circuit current value ratio using a solar simulator (manufactured by WACOM ELECTRIC CO., LTD.). The photoelectric conversion element was connected to the solar simulator such that the backside electrode on the surface side of the photoelectric conversion element is an anode and the surface electrode on the substrate side is a cathode. The photoelectric conversion element was irradiated with 100 mW/cm² of pseudo solar light obtained by passing a xenon lamp light through an air mass filter (“AM-1.5” manufactured by Nikon Corporation). A current-voltage property of the photoelectric conversion element during the irradiation was measured to obtain a current-voltage curve. From the current-voltage curve, a short circuit current value ratio was calculated. The higher the short circuit current value ratio is, the better the photoelectric conversion element is. The results are presented in the following Table 1. In the following Table 1, the humidity indicates a humidity at which the liquid film is dried in forming the light absorption layer.

TABLE 1

| | Comparative Example | Example |
|---|---|---|
| Humidity [% RH] | 35 | 65 |
| Short circuit current | 1.00 | 1.33 |

The photoelectric conversion element according to Example had a surface electrode, a backside electrode, a light absorption layer disposed between the surface electrode and the backside electrode, and a hole transport layer disposed between the backside electrode and the light absorption layer. The light absorption layer contained a conical or elliptical conical crystal. The crystal had a perovskite layer containing a perovskite compound. The hole transport layer contained an inorganic hole transporting material. The photoelectric conversion element of Example had a superior photoelectric conversion efficiency compared to the photoelectric conversion element of Comparative Example.

The photoelectric conversion element and solar battery module according to the embodiments of the present invention can be used for a solar light power generation system such a mega solar system, a solar battery, a power supply for a small-sized portable apparatus, and the like.

What is claimed is:

1. A photoelectric conversion element comprising a surface electrode, a backside electrode, a light absorption layer disposed between the surface electrode and the backside electrode, and a hole transport layer disposed between the backside electrode and the light absorption layer, wherein
the light absorption layer contains a conical or elliptical conical crystal,
the crystal has a perovskite layer containing a perovskite compound, and
the hole transport layer contains an inorganic material.

2. The photoelectric conversion element according to claim 1, wherein the inorganic material contains Cu₂O, ZnS, or NiO.

3. The photoelectric conversion element according to claim 1, wherein the inorganic material has a band gap of 2 eV or higher and an ionization potential of −5.3 eV or higher.

4. The photoelectric conversion element according to claim 1, wherein
the perovskite layer is exposed at an apex of the crystal, and
the crystal abuts on the hole transport layer at the apex.

5. The photoelectric conversion element according to claim 1, wherein the crystal has a hollow conical shape or a hollow elliptical conical shape.

6. The photoelectric conversion element according to claim 5, wherein the perovskite layer has a thickness of 50 nm or larger to 300 nm or smaller.

7. The photoelectric conversion element according to claim 5, wherein the crystal has the hollow elliptical conical shape.

8. The photoelectric conversion element according to claim 1, wherein
the crystal further comprises a first coating layer that is laminated on an outer peripheral side of the perovskite layer, and
the first coating layer contains a low refractive index material having a lower refractive index than a refractive index of the perovskite compound.

9. The photoelectric conversion element according to claim 8, wherein the low refractive index material is a polyvinyl butyral resin or a cellulose resin.

10. The photoelectric conversion element according to claim 8, wherein
the apex of the crystal is positioned on a face of the light absorption layer facing the backside electrode, and
a bottom face of the crystal is positioned on a face of the light absorption layer facing the surface electrode.

11. The photoelectric conversion element according to claim 9, wherein
the crystal further comprises a second coating layer that coats an outer periphery and an inner periphery of the perovskite layer, and
the second coating layer contains a water-repellent resin.

12. The photoelectric conversion element according to claim 1, wherein the perovskite compound is represented by the following general formula (1):
[Formula 1]
ABX₃ (1)
(in general formula (1), A represents an organic molecule, B represents a metal atom, and X represents a halogen atom).

13. The photoelectric conversion element according to claim 1, wherein
a major axis length of the crystal is 5 μm or larger to 50 μm or smaller, and
an aspect ratio of the crystal is 5 or higher to 30 or lower.

14. A solar battery module comprising a plurality of photoelectric conversion elements connected in series, wherein
the photoelectric conversion elements are the photoelectric conversion element according to claim 1.
